(19) United States
(12) Patent Application Publication
(10) Pub. No.: US 2015/0357387 A1
(43) Pub. Date: Dec. 10, 2015

(54) FLEXIBLE DISPLAY DEVICE

(71) Applicant: SAMSUNG DISPLAY CO., LTD., Yongin-City (KR)

(72) Inventors: Hoi-Kwan LEE, Yongin-City (KR); Seung-Ho KIM, Yongin-City (KR); Seung KIM, Yongin-City (KR); Ik-Hyung PARK, Yongin-City (KR); Jong-Hoon YEUM, Yongin-City (KR)

(21) Appl. No.: 14/531,028

(22) Filed: Nov. 3, 2014

(30) Foreign Application Priority Data
Jun. 5, 2014 (KR) 10-2014-0068583

(51) Int. Cl. H01L 27/32; H01L 51/52

(52) U.S. Cl. CPC H01L 27/3244; H01L 51/5237

(57) ABSTRACT

Provided is a flexible display device, including at least one flexible substrate on which a display unit is formed and a filling portion at a curved portion of the at least one flexible substrate.

### CROSS-REFERENCE TO RELATED APPLICATION

Korean Patent Application No. 10-2014-0068583, filed on Jun. 5, 2014, in the Korean Intellectual Property Office, and entitled: “Flexible Display Device,” is incorporated by reference herein in its entirety.

### BACKGROUND

1. Field

One or more embodiments relate to a flexible display device.

2. Description of the Related Art

An organic light-emitting display (OLED) device including a thin film transistor (TFT) may be used in display devices for mobile devices such as a smartphone, a digital camera, a camcorder, a portable information terminal, a laptop computer, and a tablet PC, or an electric and electronic device such as an ultra-slim TV. A flexible display device that may be easy to carry and may be applied to devices of various shapes, e.g., a flexible display device based on OLED technology, may be a next generation display device.

### SUMMARY

Embodiments may be realized by providing a flexible display device, including at least one flexible substrate on which a display unit is formed; and a filling portion at a curved portion of the at least one flexible substrate.

The flexible display device may include a slim portion at the curved portion of the at least one flexible substrate, and the filling portion may fill the slim portion.

The slim portion may be a groove, and the thickness of the curved portion of the at least one flexible substrate may be less than a thickness of other parts of the at least one flexible substrate.

The at least one flexible substrate may include a first surface and a second surface that is opposite to the first surface and is curved, and opposite sides of the first surface may face each other, and the slim portion may reduce a thickness of the at least one flexible substrate from the second surface that is an outer side when the at least one flexible substrate is curved.

The display unit may be formed on the first surface of the at least one flexible substrate.

The at least one flexible substrate may include a pair of first edges facing each other and a pair of second edges facing each other and crossing the pair of first edges, and the slim portion may extend from one of the pair of the first edges to the other of the pair of the first edges while crossing the at least one flexible substrate.

Lengths of the pair of first edges may be longer than lengths of the pair of the second edges.

A thickness of the slim portion may be adjusted by an etching process.

The filling portion may include a polymer material.

The filling portion may be bonded to the slim portion by melting the polymer material, and a surface of the filling portion that is hardened may be the same plane as the surface of the at least one flexible substrate.

The slim portion may be formed at a center portion of the at least one flexible substrate.

The filling portion may have a refractive index that is the same as a refractive index of the at least one flexible substrate.

The at least one flexible substrate may include a first flexible substrate and a second flexible substrate, the filling portion may be disposed between the first flexible substrate and the second flexible substrate, and the first flexible substrate, the filling portion, and the second flexible substrate may form a stacked structure.

The first flexible substrate and the second flexible substrate may have a first coefficient of thermal expansion (CTE), the filling portion may have a second CTE, and the second CTE may be greater than the first CTE.

The filling portion may be a polymer film.

Opposite surfaces of the filling portion may be bonded to a surface of the first flexible substrate and a surface of the second flexible substrate by applying heat and pressure.

The display unit may be formed on at least one of the first flexible substrate and the second flexible substrate.

The at least one flexible substrate may include a glass substrate.

The display unit may be formed on the at least one flexible substrate and include at least one thin film transistor; an organic light-emitting display device electrically connected to the thin film transistor; and an encapsulation layer covering the organic light-emitting display device.

### BRIEF DESCRIPTION OF THE DRAWINGS

Features will become apparent to those of skill in the art by describing in detail exemplary embodiments with reference to the attached drawings in which:

FIG. 1 illustrates a perspective view of a flexible display device in an unfolded state according to an embodiment;

FIG. 2 illustrates a perspective view of the flexible display device of FIG. 1 in a curved state;

FIG. 3 illustrates a cross-sectional view of a sub-pixel in the flexible display device of FIG. 1;

FIG. 4 illustrates a block diagram of an organic light-emitting display (OLED) device of FIG. 3;

FIG. 5 illustrates a perspective view of a flexible display device according to an embodiment;

FIG. 6 illustrates a side view of the flexible display device of FIG. 5 seen from an opposite direction;

FIG. 7 illustrates a side view of the flexible display device of FIG. 5 in a curved state in a direction; and

FIG. 8 illustrates a side view of a flexible display device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present.

While such terms as “first”, “second,” etc., may be used to describe various components, such components must not be limited to the above terms. The above terms are used only to distinguish one component from another.

The terms used in the present specification are merely used to describe particular embodiments, and are not intended to be limiting. An expression used in the singular encompasses the expression of the plural, unless it has a clearly different meaning in the context. In the present specification, it is to be understood that the terms such as “including”, “having”, and “comprising” are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Hereinafter, a flexible display device will be described in detail by explaining exemplary embodiments with reference to the attached drawings. Like reference numerals in the drawings denote like elements. Expressions such as “at least one of,” when preceding a list of elements, modify the entire list of elements and do not modify the individual elements of the list.

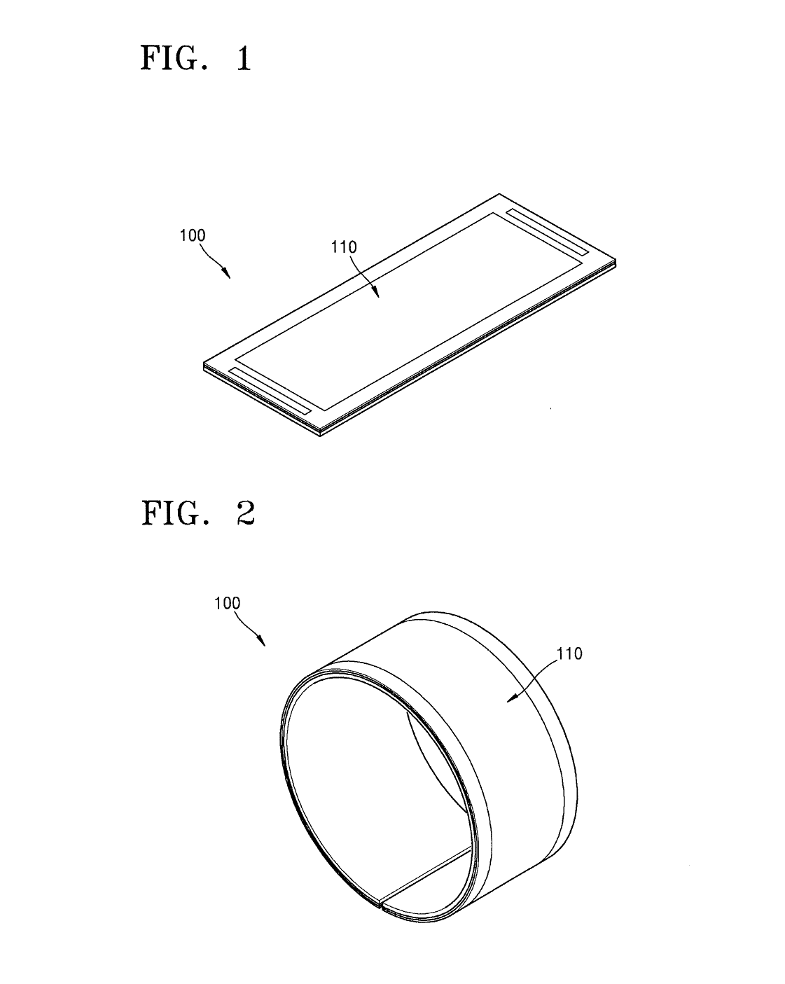

FIG. 1 illustrates a perspective view of a flexible display device 100 according to an embodiment in an unfolded state, and FIG. 2 illustrates a perspective view of the flexible display device 100 in a curved state.

Referring to FIGS. 1 and 2, the flexible display device 100 may include a flexible display panel 110 for displaying images. The flexible display panel 110 may include a thin film for displaying images, and moreover, various functional layers such as a touch screen, a polarization plate, and a window cover.

According to an embodiment, the flexible display device 100 may be, for example, an organic light-emitting diode (OLED) display device. Embodiments may be applied to other types of flexible display devices, for example, a liquid crystal display (LCD) device, a field emission display (FED) device, and an electronic paper display device.

A user of the flexible display device 100 may see images on the flexible display device 100 in an unfolded state or a curved state according to necessity of the user.

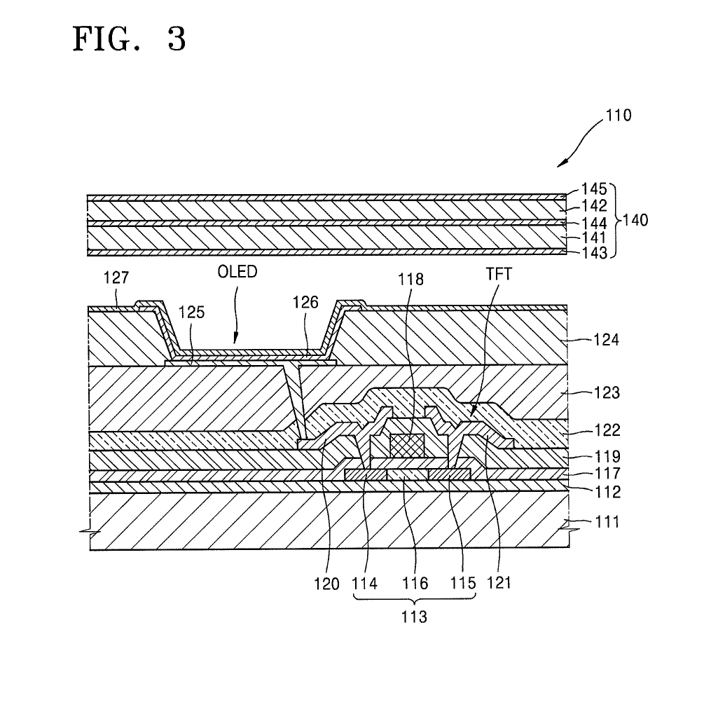

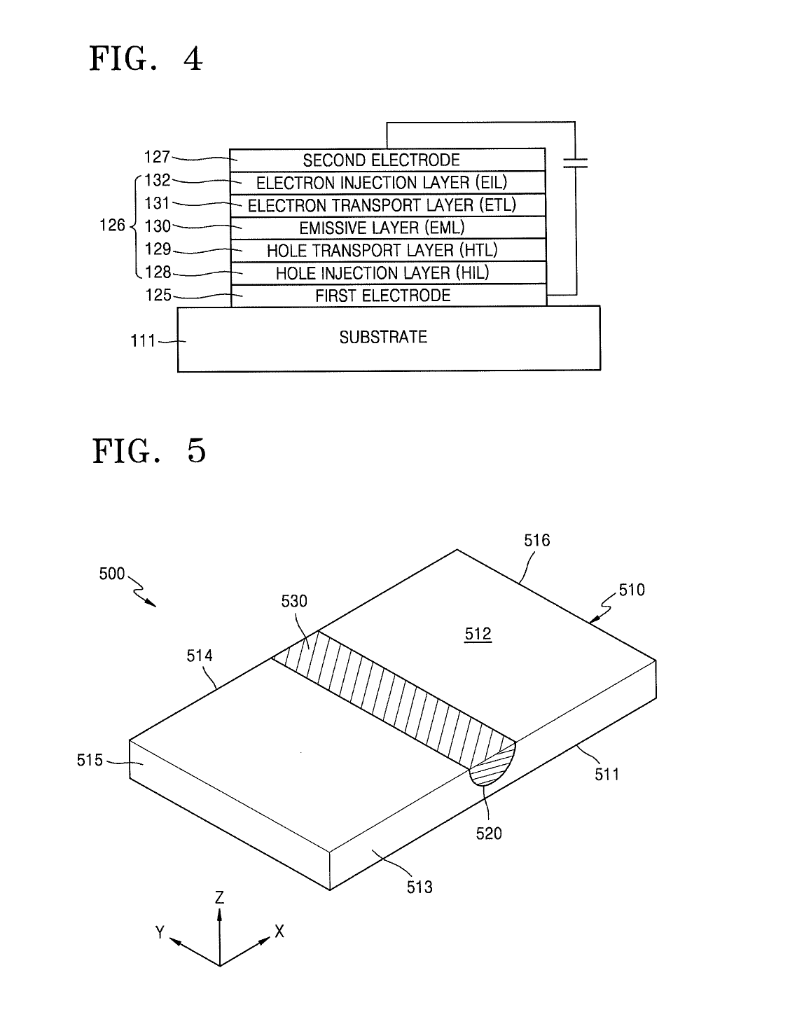

FIG. 3 illustrates a cross-sectional view of a sub-pixel in the flexible display device 100 of FIG. 1, and FIG. 4 illustrates a cross-sectional view of an OLED in FIG. 3.

Each of the sub-pixels may include at least one thin film transistor (TFT) and an OLED. A structure of the TFT is not limited to the structure shown in FIG. 3, and the number of TFTs and the structure of the TFT may be variously modified.

Referring to FIGS. 3 and 4, a flexible substrate 111 may be provided in the flexible display panel 110. The flexible substrate 101 may include an insulating material having flexibility. For example, the flexible substrate 111 may be a glass substrate of a thin film type. In an embodiment, the flexible substrate 111 may be a polymer substrate.

The flexible substrate 111 may be transparent, semi-transparent, or opaque.

A barrier layer 112 may be formed on the flexible substrate 111. The barrier layer 112 may be formed on an entire upper surface of the flexible substrate 111. The barrier layer 112 may include an inorganic layer or an organic layer. For example, the barrier layer 112 may be formed of an inorganic material such as silicon oxide (SiOₓ), silicon nitride (SiNₓ), silicon oxynitride (SiON), aluminum oxide (AlO), aluminum nitride (AlON), or an organic material such as acryl, polyimide, or polyester.

The barrier layer 112 may be formed to have a single-layered or a multi-layered structure. The barrier layer 112 may block oxygen and moisture, prevent moisture or impurities from diffusing into the flexible substrate 111, and provide a planarized surface on the flexible substrate 111.

A TFT may be formed on the barrier layer 112. The TFT according to an embodiment may be a top gate-type TFT. In an embodiment, another type of TFT such as a bottom gate-type may be provided.

A semiconductor active layer 113 may be formed on the barrier layer 112. A source region 114 and a drain region 115 may be formed by doping the semiconductor active layer 113 with N type impurity ions or P type impurity ions. A region between the source region 114 and the drain region 115 may be a channel region 116 where impurities are not doped.

If the semiconductor active layer 113 is formed of polysilicon, the semiconductor active layer 113 may be formed of amorphous silicon first, and then, the amorphous silicon may be crystallized into polysilicon.

In an embodiment, the semiconductor active layer 113 may be formed of oxide semiconductor. For example, the oxide semiconductor may include oxide of a material selected from groups IV, XII, XIII, and XIV metal elements such as zinc (Zn), indium (In), gallium (Ga), tin (Sn), cadmium (Cd), germanium (Ge), and hafnium (Hf) and combinations thereof.

A gate insulating layer 117 may be formed on the semiconductor active layer 113. The gate insulating layer 117 may include an inorganic layer formed of, for example, silicon oxide, silicon nitride, or metal oxide. The gate insulating layer 117 may have a single-layered or a multi-layered structure.

A gate electrode 118 may be formed on the gate insulating layer 117. The gate electrode 118 may include a single-layered structure or a multi-layered structure of Au, Ag, Cu, Ni, Pt, Pd, Al, Mo, or Cr, or an alloy such as Al:Nd or Mo:W.

An interlayer insulating layer 119 may be formed on the gate electrode 118. The interlayer insulating layer 119 may be formed as an inorganic layer such as silicon oxide or silicon nitride.

A source electrode 120 and a drain electrode 121 may be formed on the interlayer insulating layer 119. Contact holes may be formed in the gate insulating layer 117 and the interlayer insulating layer 119 by removing part of the gate insulating layer 117 and the interlayer insulating layer 119, and the source electrode 120 and the drain electrode 121 may be electrically connected respectively to the source region 114 and the drain region 115 via the contact holes.

A passivation layer 122 may be formed on the source electrode 120 and the drain electrode 121. The passivation layer 122 may be formed as an inorganic layer such as silicon oxide or silicon nitride, or an organic layer.

A planarization layer 123 may be formed on the passivation layer 122. The planarization layer 123 may be formed as an organic layer including a material such as acryl, polyimide, or benzocyclobutene (BCB).

An OLED may be formed on the TFT.

The OLED may include a first electrode 125, a second electrode 127, and an intermediate layer 126 disposed between the first electrode 125 and the second electrode 127.

The first electrode 125 may be electrically connected to one of the source electrode 120 and the drain electrode 121 via a contact hole. The first electrode 125 may correspond to a pixel electrode.

The first electrode 125 may act as an anode and may be formed of various conductive materials. The first electrode 125 may be formed as a transparent electrode or a reflective electrode. For example, the first electrode 125 may be formed as a transparent electrode, and the first electrode 125 may include indium tin oxide (ITO), indium zinc oxide (IZO), ZnO, or In₂O₃. The first electrode 125 may be a reflective electrode, a reflective layer may be formed of Ag, Mg, Al, Pt, Pd, Au, Ni, Nd, Ir, Cr, or a compound thereof, and then, a transparent electrode may be formed of ITO, IZO, ZnO, or In₂O₃ on the reflective layer.

A pixel-defining layer (PDL) 124 may be formed on the planarization layer 123 and may cover edges of the first electrode 125 of the OLED. The PDL 124 may define an emission area in each of the sub-pixels by surrounding the edges of the first electrode 125.

The PDL 124 may be formed of an organic material or an inorganic material. For example, the PDL 124 may be formed of an organic material such as polyimide, polyamide, BCB, acryl resin, or phenol resin, or an inorganic material such as SiNₓ. The PDL 124 may be formed as a single-layered structure or a multi-layered structure.

The intermediate layer 126 may be formed on the first electrode 125, at a region of the first electrode 125 that may be exposed by partially etching the PDL 124. The intermediate layer 126 may be formed by a deposition process.

The intermediate layer 126 may be formed of a low molecular weight organic material or a high molecular weight organic material. As shown in FIG. 4, the intermediate layer 126 may include an emission layer (EML) 130, and may further include at least one selected from a hole injection layer (HIL) 128, a hole transport layer (HTL) 129, an electron transport layer (ETL) 131, and an electron injection layer (EIL) 132.

Referring back to FIG. 3, the second electrode 127 may be formed on the intermediate layer 126. The second electrode 127 may correspond to a common electrode. The second electrode 127 may be formed as a transparent electrode or a reflective electrode, like the first electrode 125.

The first electrode 126 may be formed to have a shape corresponding to an opening in each of the sub-pixels. In an embodiment, the second electrode 127 may be formed completely on a display unit. In an embodiment, the second electrode 127 may be formed in a certain pattern, instead completely disposed. The first electrode 125 and the second electrode 127 may be formed at opposite locations.

In addition, the first electrode 125 and the second electrode 127 may be insulated from each other by the intermediate layer 126. Voltages may be applied to the first and second electrodes 125 and 127, and the intermediate layer 126 may emit visible rays to form images that the user may recognize.

An encapsulation layer 140 may be formed on the OLED. The encapsulation layer 140 may protect the intermediate layer 126 and other thin films against external moisture or oxygen.

The encapsulation layer 140 may have a structure in which at least one organic layer and at least one inorganic layer are stacked. For example, the encapsulation layer 140 may have a structure in which organic layers 141 and 142 such as epoxy, polyimide, polyethylene terephthalate, polycarbonate, polyethylene, and polyacrylate, and inorganic layers 143, 144, and 145 such as silicon oxide (SiO₂), silicon nitride (SiNₓ), aluminum oxide (Al₂O₃), titanium oxide (TiO₂), zirconium oxide (ZrOₓ), and zinc oxide (ZnO), are stacked.

The encapsulation layer 140 may have a structure in which at least one organic layer is provided and at least two inorganic layers are provided. The exposed uppermost inorganic layer 145 of the encapsulation layer 140 may prevent moisture from infiltrating into the OLED.

The flexible display device 100 having the above structure may be curved in a direction, and the flexible substrate 111 may be damaged, for example, due to stress applied to the flexible display device 100.

The flexible substrate 111 may be formed of a plastic material, and thermal stability and scratch characteristics may be degraded. In an embodiment, the flexible substrate 111 may be formed as a glass substrate. If the flexible substrate 111 is formed of a material having a weak brittleness such as glass, the flexible substrate 111 may be damaged, for example, due to tensile stress applied to the flexible display device 100.

According to an embodiment, the flexible substrate 111 may be curved in a direction, and a filling unit may be provided to prevent damage to the flexible substrate 111.

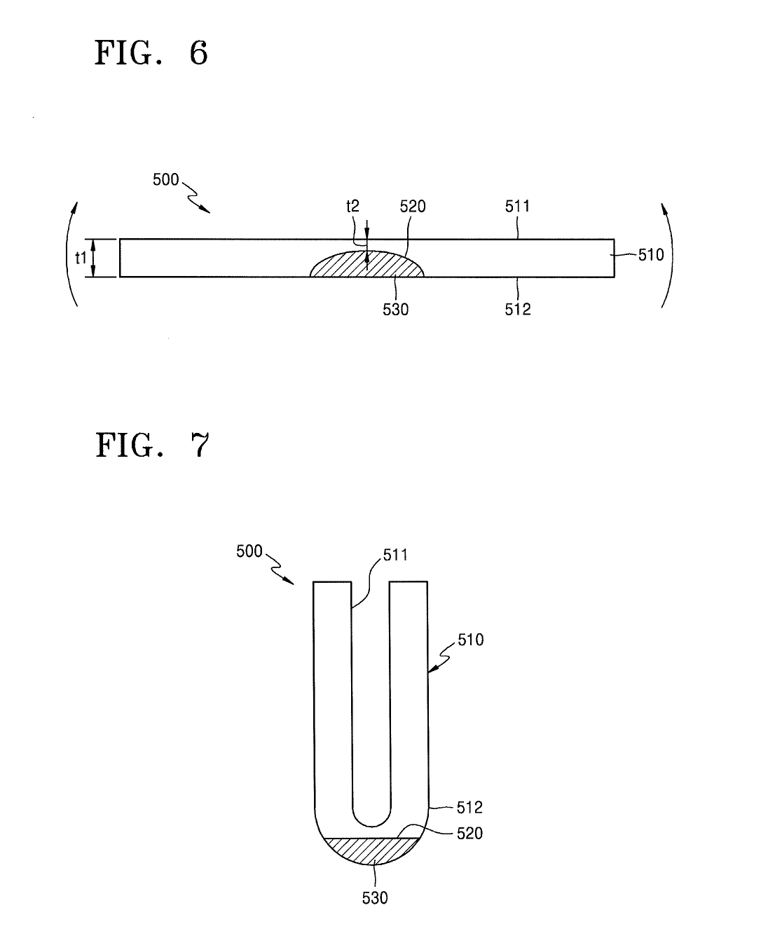

FIG. 5 illustrates a perspective view of the flexible display device 100 according to an embodiment, FIG. 6 illustrates a side view of the flexible display device 100 of FIG. 5, as seen from a side, and FIG. 7 illustrates a side view of the flexible display device 100 of FIG. 5, which is curved in a direction.

Referring to FIGS. 5 through 7, the flexible display apparatus 100 may include at least one flexible substrate 510. The flexible substrate 510 may be a glass substrate. The flexible substrate 510 may include a first surface 511 and a second surface 512 opposite to the first surface 511. A display unit for displaying images may be formed on the first surface 511 of the flexible substrate 510.

The flexible substrate 510 may be configured to be curved in a direction. The flexible substrate 510 may include a winding substrate, a curved substrate, or a foldable substrate.

In an embodiment, the flexible substrate 510 may have a rectangular lateral cross-sectional area when viewed along the x-axis of FIG. 5. In an embodiment, the flexible substrate 510 may have another lateral section shape, for example, a circular, an oval, a square, or a polygonal lateral section.

The flexible substrate 510 may have a pair of first edges 513 and 514 facing each other, and a pair of second edges 515 and 516 facing each other and crossing the first edges 513 and 514.

In an embodiment, the pair of first edges 513 and 514 may correspond to long sides facing each other, and the pair of second edges 515 and 516 may correspond to short sides facing each other. Lengths of the pair of first edges 513 and 514 extending in an X-axis direction of the flexible substrate 510 may be greater than lengths of the pair of second edges 515 and 516 extending in a Y-axis direction of the flexible substrate 510.

A slim portion 520 may be formed at a curved portion of the flexible substrate 510. The slim portion 520 may be a groove formed by reducing a thickness of the curved portion in the flexible substrate 510 to be less than that of any other portion of the flexible substrate 510. For example, a thickness t1 of the flexible substrate 510 may be 100 μm, while a thickness t2 of the slim portion 520 may be 30 μm.

The slim portion 520 may be formed in various ways. For example, the slim portion 520 may be formed by a wet etching process such as a dip method, a spray method, and a down-flow method. The thickness of the curved portion in the flexible substrate 510 may be adjusted by wet etching the slim portion 520.

The flexible substrate 510 may be curved, and opposite sides of the first surface 511 (left and right sides in FIG. 6) may face each other. In an embodiment, the flexible substrate 510 may be curved in a ‘U’-shape (see FIG. 7).

The slim portion 520 may be formed by reducing the thickness of the flexible substrate 510 from the second surface 512 that is opposite to the first surface 511. The second surface 512 may be an outer surface when the flexible substrate 510 is curved.

In an embodiment, the slim portion 520 may be formed between the pair of the first edges 513 and 514 of the flexible substrate 510. For example, the slim portion 520 may extend from a first portion in the first edge 513 to a second portion of the first edge 514 across the flexible substrate 510.

In an embodiment, the slim portion 520 may be formed at a center portion of the flexible substrate 510. In an embodiment, the location of the slim portion 520 may be changed according to where the location of the curved portion of the flexible substrate 510.

In addition, the slim portion 520 may have a semi-circular cross-section.

The flexible substrate 510 may be curved in a direction, and the portion where the slim portion 520 is formed may have a smaller thickness than that of the other part of the flexible substrate 520. A filling portion 530 may be formed in the slim portion 520, and damage, for example, due to the small thickness of the slim portion 520, may be prevented.

The filling portion 530 may be a polymer material filled in the slim portion 520, for example, ethylene-vinyl acetate copolymer (EVA). The filling portion 530 may be filled in the slim portion 520 in various ways. For example, a polymer material may be melted and then, bonded to the slim portion 520. A surface of the filling portion 530 that may be hardened may be the same plane as the surface of the flexible substrate 510.

A refractive index of the filling portion 530 may be the same as that of the flexible substrate 510.

A flexible substrate 510 having the above structure may include the slim portion 520 at the curved portion, and a flexural strength of the flexible display device 500 may be improved. Also, the filling portion 530 may fill in the slim portion 520, and the strength of the flexible substrate 510 may be reinforced.

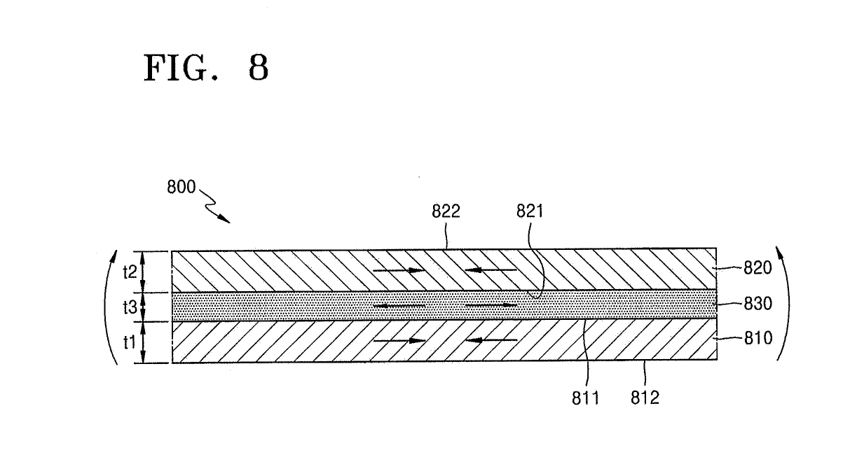

FIG. 8 illustrates a side view of a flexible display device 800 according to an embodiment.

Referring to FIG. 8, the flexible display device 800 may include one or more flexible substrates, for example, a first flexible substrate 810 and a second flexible substrate 820. The first and second flexible substrates 810 and 820 may be formed as glass substrates.

The first and second flexible substrates 810 and 820 may be curved in a direction. For example, the first and second flexible substrates 810 and 820 may be wound as a cylinder, curved at a predetermined angle, or folded.

A filling portion 830 may be formed in a curved portion of the first and second flexible substrates 810 and 820.

The first flexible substrate 810 may include a first surface 811 and a second surface 812 that is opposite to the first surface 811. The second flexible substrate 820 may include a first surface 821 facing the first surface 811 of the first flexible substrate 810, and a second surface 822 that is opposite to the first surface 821.

A display unit for displaying images may be formed on the second surface 812 of the first flexible substrate 810 or the second surface 822 of the second flexible substrate 820, according to a curved direction of the flexible display device 800.

For example, the flexible display device 800 may be curved in a direction, opposite sides of the second surface 822 (left and right sides of FIG. 8) of the second flexible substrate 820 may face each other, and the display unit may be formed on the second surface 822 of the second flexible substrate 820.

The filling portion 830 may be disposed between the first flexible substrate 810 and the second substrate 820. The first flexible substrate 810, the filling portion 830, and the second flexible substrate 830 may form a stacked structure. Opposite surfaces of the filling portion 830 may respectively contact the first surface 811 of the first flexible substrate 810 and the first surface 821 of the second flexible substrate 820.

A thickness t1 of the first flexible substrate 810 and a thickness t2 of the second flexible substrate 820 may be equal to each other. In an embodiment, the thickness t1 of the first flexible substrate 810 and the thickness t2 of the second flexible substrate 820 may range from about 20 μm to about 50 μm, and a thickness (t3) of the filling portion 830 may be less than 100 μm.

The first and second flexible substrates 810 and 820 may be curved in a direction, the filling unit 830 may be a polymer film that has superior characteristics against curvature, for example, an EVA, and damage to the flexible display device 800 may be prevented. The filling portion 830 may be bonded to the first and second flexible substrates 810 and 820 in various ways. For example, the bonding may be performed by applying heat and pressure to the filling portion 830, which may be formed as a polymer film, located on one of the surfaces of the first and second flexible substrates 810 and 820 in a vacuum environment.

The stacked structure, in which the filling portion 830 may be disposed between the first and second flexible substrates 810 and 820, may have different thermal expansion coefficients, and thermal reinforcement characteristics may be improved.

For example, the first flexible substrate 810 and the second flexible substrate 820 may have a first coefficient of thermal expansion (CTE), and the filling portion 830 may have a second CTE that is different from the first CTE. The second CTE of the filling portion 830 may be greater than the first CTE of the first flexible substrate 810 and the second flexible substrate 820.

In addition, a refractive index of the filling portion 830 may be the same as those of the first and second flexible substrates 810 and 820.

When a flexible display device 800 having the above stacked structure is curved in a direction, compressive stress may be applied to the first flexible substrate 810 and the second flexible substrate 820 and tensile stress may be applied to the filling portion 830 as denoted by arrows. Therefore, the flexural strength of the flexible display device 800 may be improved.

Also, a thermal reinforcement effect, for example, due to the difference between the CTEs in the flexible display device 800, may be present, the strength of the flexible display device 800 may be improved, and the flexible display device 800 may have reliable flexibility.

As described above, the flexible display device may prevent damage to the flexible substrate when being curved in a direction.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A flexible display device, comprising:
at least one flexible substrate on which a display unit is formed; and
a filling portion at a curved portion of the at least one flexible substrate.

2. The flexible display device as claimed in claim 1, comprising a slim portion at the curved portion of the at least one flexible substrate, the filling portion filling the slim portion.

3. The flexible display device as claimed in claim 2, wherein the slim portion is a groove, the thickness of the curved portion of the at least one flexible substrate being less than a thickness of other parts of the at least one flexible substrate.

4. The flexible display device as claimed in claim 3, wherein the at least one flexible substrate includes a first surface and a second surface that is opposite to the first surface and is curved, and opposite sides of the first surface face each other, the slim portion reducing a thickness of the at least one flexible substrate from the second surface that is an outer side when the at least one flexible substrate is curved.

5. The flexible display device as claimed in claim 4, wherein the display unit is formed on the first surface of the at least one flexible substrate.

6. The flexible display device as claimed in claim 3, wherein the at least one flexible substrate includes a pair of first edges facing each other and a pair of second edges facing each other and crossing the pair of first edges, and the slim portion extends from one of the pair of the first edges to the other of the pair of the first edges while crossing the at least one flexible substrate.

7. The flexible display device as claimed in claim 6, wherein lengths of the pair of first edges are longer than lengths of the pair of the second edges.

8. The flexible display device as claimed in claim 3, wherein a thickness of the slim portion is adjusted by an etching process.

9. The flexible display device as claimed in claim 2, wherein the filling portion includes a polymer material.

10. The flexible display device as claimed in claim 9, wherein the filling portion is bonded to the slim portion by melting the polymer material, and a surface of the filling portion that is hardened is the same plane as the surface of the at least one flexible substrate.

11. The flexible display device as claimed in claim 2, wherein the slim portion is formed at a center portion of the at least one flexible substrate.

12. The flexible display device as claimed in claim 2, wherein the filling portion has a refractive index that is the same as a refractive index of the at least one flexible substrate.

13. The flexible display device as claimed in claim 1, wherein the at least one flexible substrate includes a first flexible substrate and a second flexible substrate, the filling portion is disposed between the first flexible substrate and the second flexible substrate, and the first flexible substrate, the filling portion, and the second flexible substrate form a stacked structure.

14. The flexible display device as claimed in claim 13, wherein the first flexible substrate and the second flexible substrate have a first coefficient of thermal expansion (CTE), the filling portion has a second CTE, and the second CTE is greater than the first CTE.

15. The flexible display device as claimed in claim 13, wherein the filling portion is a polymer film.

16. The flexible display device as claimed in claim 15, wherein opposite surfaces of the filling portion are bonded to a surface of the first flexible substrate and a surface of the second flexible substrate by applying heat and pressure.

17. The flexible display device as claimed in claim 13, wherein the display unit is formed on at least one of the first flexible substrate and the second flexible substrate.

18. The flexible display device as claimed in claim 1, wherein the at least one flexible substrate includes a glass substrate.

19. The flexible display device as claimed in claim 1, wherein the display unit is formed on the at least one flexible substrate and includes:
at least one thin film transistor;
an organic light-emitting display device electrically connected to the thin film transistor; and
an encapsulation layer covering the organic light-emitting display device.
